(19) United States
(12) Patent Application Publication
(10) Pub. No.: US 2026/0082838 A1
(43) Pub. Date: Mar. 19, 2026

(54) MASK STRUCTURE AND MANUFACTURING METHOD OF SEMICONDUCTOR DEVICE USING THE SAME

(71) Applicant: SAMSUNG ELECTRONICS CO., LTD., Suwon-si (KR)

(72) Inventors: Hoin LEE, Suwon-si (KR); Hyeonok JUNG, Suwon-si (KR)

(73) Assignee: SAMSUNG ELECTRONICS CO., LTD., Suwon-si (KR)

(21) Appl. No.: 19/190,173

(22) Filed: Apr. 25, 2025

(30) Foreign Application Priority Data
Sep. 19, 2024 (KR) 10-2024-0126845

(51) Int. Cl. H01L 21/308

(52) U.S. Cl. CPC H10P 50/692

(57) ABSTRACT

Provided is a method of manufacturing a semiconductor device, the method including: forming a mask stack, wherein the substrate includes a first region and a second region with different active region densities and an adjacent region between the first region and the second region; forming, on the capping mask layer, a first etch pattern that does not cover the first region and is on the second region and the adjacent region; forming a capping mask line by removing a portion of the capping mask layer by using the first etch pattern as an etch mask; forming a second etch pattern on the capping mask; and forming a mask pattern by removing a portion of the mask stack by using the capping mask line and the second etch pattern as etch masks.

### CROSS-REFERENCE TO RELATED APPLICATION

This application is based on and claims priority to Korean Patent Application No. 10-2024-0126845, filed on Sep. 19, 2024, in the Korean Intellectual Property Office, the disclosure of which is incorporated by reference herein in its entirety.

### BACKGROUND

### 1. Field

The disclosure relates to a mask structure and a method of manufacturing a semiconductor device using the mask structure. More particularly, the disclosure relates to a mask structure used during manufacturing processes of a semiconductor device that includes device isolation regions within a cell array region and a core region or peripheral circuit region (hereinafter, referred to as “peripheral circuit region”) located near the cell array region, and a method of manufacturing a semiconductor device by using the mask structure.

### 2. Description of Related Art

With recent developments in the semiconductor industry and increasing user demands, electronic devices have become highly integrated and highly powered, and accordingly, semiconductor devices, which are core components of the electronic devices, are required to achieve high integration and high performance. As semiconductor devices become highly integrated, feature sizes thereof are reduced, and interface regions between cell array regions and peripheral circuit regions of the semiconductor devices decrease in dimension such that horizontal widths of the interface regions become smaller than minimum margin horizontal widths required during a patterning process of active regions. To this end, during a process of forming active regions, a problem has arisen in which parasitic active regions are formed due to parasitic mask patterns formed in the interface regions or peripheral circuit regions.

### SUMMARY

Provided is a mask structure capable of reducing or preventing the formation of parasitic active regions that are formed as parasitic mask patterns are formed in an interface region or peripheral circuit region, and a method of manufacturing a semiconductor device by using the mask structure.

Further provided is a mask structure in which active regions may be formed without a separate trimming process of removing the parasitic mask patterns and a method of manufacturing a semiconductor device by using the mask structure.

According to an aspect of the disclosure, a method of manufacturing a semiconductor device includes: forming a mask stack on a substrate, wherein the substrate includes a first region, a second region and an adjacent region between the first region and the second region, and wherein the first region and the second region have different active region densities; forming a capping mask layer on the mask stack; forming, on the capping mask layer, a first etch pattern that does not cover the first region and is on the second region and the adjacent region; forming a capping mask line by removing a portion of the capping mask layer by using the first etch pattern as an etch mask and exposing a portion of the mask stack; forming a second etch pattern on the capping mask line and the exposed portion of the mask stack; forming a mask pattern by removing a portion of the mask stack using the capping mask line and the second etch pattern as etch masks; and forming a plurality of trenches in the substrate by using the mask pattern as an etch mask, wherein the second etch pattern includes: a plurality of first etch mask lines extending in one direction in the first region and the adjacent region, wherein the plurality of first etch mask lines are separated from each other; and a second etch mask line on the second region.

According to an aspect of the disclosure, a method of manufacturing a semiconductor device includes: sequentially depositing a dual mask layer, a variable mask layer, and a capping mask layer on a substrate, the substrate including a cell array region, a peripheral circuit region, and an interface region, wherein the interface region is between the cell array region and the peripheral circuit region; forming, on the capping mask layer, a first etch pattern that does not cover the cell array region and is on the interface region and the peripheral circuit region; forming a capping mask line by removing a portion of the capping mask layer by using the first etch pattern as an etch mask and exposing a portion of the variable mask layer; forming a second etch pattern on the capping mask line and the exposed portion of the variable mask layer; and etching the variable mask layer using the capping mask line and the second etch pattern as etch masks, wherein the second etch pattern includes: a plurality of first etch mask lines that are spaced apart from each other in the cell array region and the interface region; and a second etch mask line on the peripheral circuit region.

According to an aspect of the disclosure, a mask structure includes: a hard mask layer on a substrate, the substrate including a first region, a second region, and an adjacent region between the first region and the second region, wherein the first region and the second region have different active region densities; a dual mask layer including a carbon-containing layer on the hard mask layer; a variable mask layer including a nitride layer on the dual mask layer; and a capping mask line including an oxide layer on the variable mask layer, wherein the capping mask line is on the adjacent region and the second region and does not cover the first region.

The disclosure is not limited to the above description, and other aspects and features may be clearly understood by one of ordinary skill in the art from the descriptions provided hereinafter.

### BRIEF DESCRIPTION OF DRAWINGS

The above and other aspects and features of certain embodiments of the present disclosure will be more clearly understood from the following detailed description taken in conjunction with the accompanying drawings, in which:

FIG. 1 is a plan view of a schematic structure of a semiconductor device, according to one or more embodiments;

FIG. 2 is an enlarged view of region “EX” of FIG. 1; and

FIGS. 3A to 16B are diagrams illustrating a method of manufacturing a semiconductor device according to one or more embodiments,

wherein, specifically, FIGS. 3A, 4A, 5A, 6A, 7A, 8A, 9A, 10A, 11A, 12A, 13A, 14A, 15A, and 16A are each a diagram corresponding to region “EX” of FIG. 1, and

FIGS. 3B, 4B, 5B, 6B, 7B, 8B, 9B, 10B, 11B, 12B, 13B, 14B, 15B, and 16B are diagrams corresponding to cross-sections taken along a line X1-X1′ of FIGS. 3A, 4A, 5A, 6A, 7A, 8A, 9A, 10A, 11A, 12A, 13A, 14A, 15A, and 16A, respectively.

### DETAILED DESCRIPTION

Hereinafter, one or more embodiments of the disclosure will be described in detail with reference to the attached drawings. Like reference numerals in the drawings denote like elements, and repeated descriptions thereof will be omitted.

It will be understood that when an element is referred to as being “connected” with or to another element, it can be directly or indirectly connected to the other element.

Also, when a part “includes” or “comprises” an element, unless there is a particular description contrary thereto, the part may further include other elements, not excluding the other elements.

Throughout the description, when a member is “on” another member, this includes not only when the member is in contact with the other member, but also when there is another member between the two members.

As used herein, the expressions “at least one of a, b or c” and “at least one of a, b and c” indicate “only a,” “only b,” “only c,” “both a and b,” “both a and c,” “both b and c,” and “all of a, b, and c.”

It will be understood that, although the terms “first”, “second”, “third”, etc., may be used herein to describe various elements, is the disclosure should not be limited by these terms. These terms are only used to distinguish one element from another element.

As used herein, the singular forms “a,” “an” and “the” are intended to include the plural forms as well, unless the context clearly indicates otherwise.

With regard to any method or process described herein, an identification code may be used for the convenience of the description but is not intended to illustrate the order of each step or operation. Each step or operation may be implemented in an order different from the illustrated order unless the context clearly indicates otherwise. One or more steps or operations may be omitted unless the context of the disclosure clearly indicates otherwise.

As used herein, where a layer or structure is described as “covering” another layer or structure, such layer or structure may also be described as being “on” the layer or structure on which it is formed, and such layer or structure may partially or completely “cover” the layer or structure on which it is “on” or on which it is formed.

In the present disclosure, a horizontal direction may include a first horizontal direction (an X direction) and a second horizontal direction (a Y direction) which cross each other. A direction crossing the first horizontal direction (the X direction) and the second horizontal direction (the Y direction) may be referred to as a vertical direction (a Z direction). In the present disclosure, the vertical level may be referred to as a height level of any structure along the vertical direction (the Z direction).

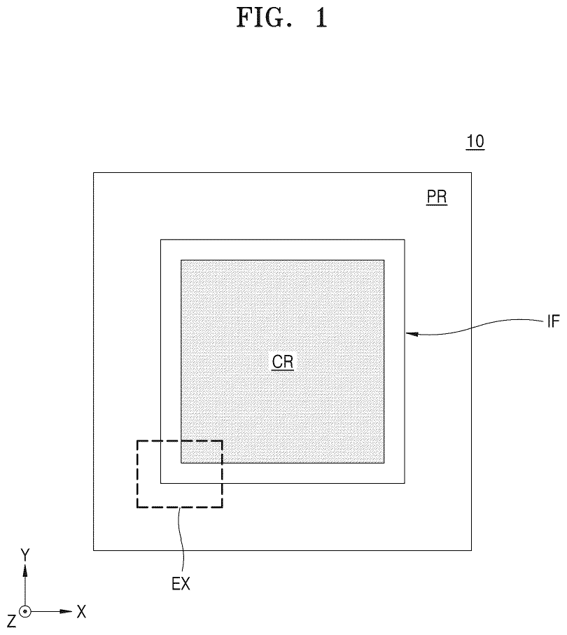

FIG. 1 is a plan view of a schematic structure of a semiconductor device 10 according to one or more embodiments.

Referring to FIG. 1, the semiconductor device 10 may include a first region CR, a second region PR, and an adjacent region IF between the first region CR and the second region PR. In the first region CR and the second region PR, densities of active regions may be different. In one or more embodiments, the first region CR may be a high-density region where the density of the active region is relatively high, while the second region PR may be a low-density region where the density of the active region is relatively low.

In one or more embodiments, the first region CR may be a cell array region of the semiconductor device 10. In one or more embodiments, the first region CR may form a memory cell array region of a volatile memory device or a non-volatile memory device. The memory cell array region may be a memory cell array region of dynamic random access memory (DRAM), magnetic RAM (MRAM), static RAM (SRAM), phase change RAM (PRAM), resistance RAM (RRAM), or ferroelectric RAM (FRAM). The first region CR may include a memory cell of any one type selected from among a DRAM memory cell, an MRAM memory cell, an SRAM memory cell, a PRAM memory cell, an RRAM memory cell, and an FRAM memory cell. The first region CR may include a unit memory cell including a transistor and a capacitor or a unit memory cell including a switching device and a variable resistor.

In the second region PR, a plurality of peripheral circuits that are electrically connected to a plurality of cell arrays in the first region CR may be formed. Similar to a core region or a peripheral circuit region (hereinafter, referred to as the “peripheral circuit region”), the second region PR may include a region where no cell arrays are formed.

In the adjacent region IF, a plurality of conductive lines installed to establish electrical connections between the first region CR and the second region PR and a plurality of insulating structures for insulation of the first region CR from the second region PR may be arranged. In one or more embodiments, no active region may be formed in the adjacent region IF. In the present disclosure, the adjacent region IF may be referred to as “interface region.”

FIG. 1 shows that the second region PR surrounds the first region CR, but it is only an example. One or more embodiments are not limited to the arrangement shown in FIG. 1, and the first region CR and the second region PR may be arranged in any suitable configuration according to necessity.

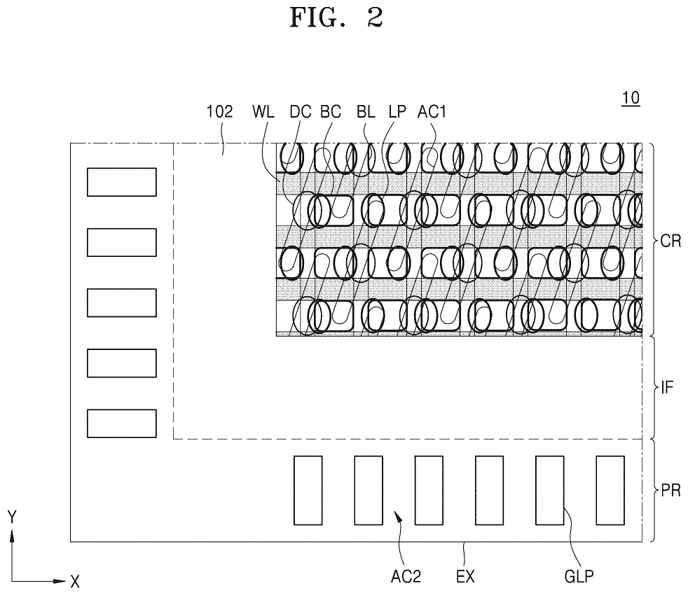

FIG. 2 is an enlarged view of region “EX” of FIG. 1.

Referring to FIG. 2, the semiconductor device 10 includes a substrate 102 that includes the first region CR and the second region PR, the first region CR and the second region PR having different densities of active regions, and the adjacent region IF that is adjacent to the first region CR within the second region PR. In one or more embodiments, the first region CR may be a cell array region, and the second region PR may be a peripheral circuit region.

The semiconductor device 10 may include a plurality of first active regions AC1 in the first region CR. The first active regions AC1 may be arranged diagonally relative to the first horizontal direction X and the second horizontal direction Y.

A plurality of word lines WL may extend in parallel with each other in the first horizontal direction X by crossing the first active regions AC1. On the word lines WL, a plurality of bit lines BL may extend in parallel with each other in the second horizontal direction Y intersecting the first horizontal direction X. The bit lines BL may be respectively connected to the first active regions AC1 through direct contacts DC.

A plurality of buried contacts BC may be formed between two bit lines BL, which are adjacent to each other, from among the bit lines BL. In one or more embodiments, the buried contacts BC may be arranged in a row in the first horizontal direction X and the second horizontal direction Y. On the buried contacts BC, a plurality of conductive landing pads LP may be formed. The buried contacts BC and the conductive landing pads LP may function as connectors for connecting lower electrodes of the capacitors formed on the bit lines BL to the first active regions AC1. At least a portion of each conductive landing pad LP may vertically overlap the buried contact BC.

In the second region PR, a plurality of gate line patterns GLP forming a plurality of logic transistors may be arranged. The gate line patterns GLP may extend from a portion close to the first region CR towards a portion farther away, but one or more embodiments are not limited thereto. In addition, the shapes of the gate line patterns GLP shown in FIG. 2 are only examples, and the gate line patterns GLP may respectively have different widths, be curved, or extend in different horizontal directions with varying widths.

The semiconductor device 10 may include a plurality of second active regions AC2 in the second region PR. In the second region PR, components other than the gate line patterns GLP and the second active regions AC2 are omitted for convenience of illustration.

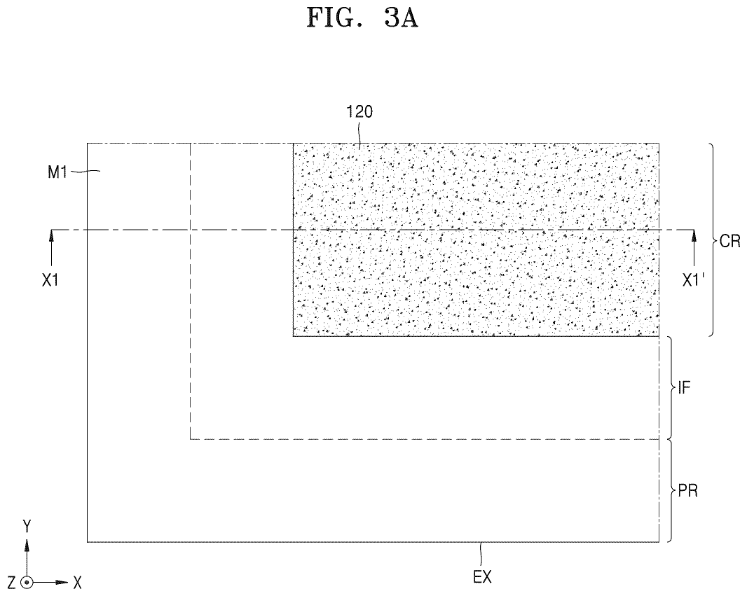

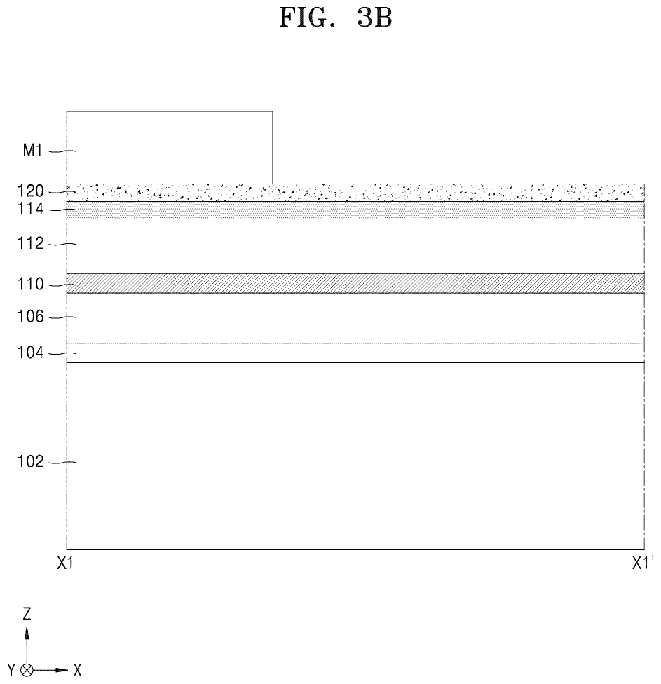

Hereinafter, a method of manufacturing a semiconductor device according to one or more embodiments is described with reference to FIGS. 3A to 16B.

FIGS. 3A to 16B are diagrams illustrating a method of manufacturing a semiconductor device according to one or more embodiments.

Specifically, FIGS. 3A, 4A, 5A, 6A, 7A, 8A, 9A, 10A, 11A, 12A, 13A, 14A, 15A, and 16A are each a diagram corresponding to region “EX” of FIG. 1, and FIGS. 3B, 4B, 5B, 6B, 7B, 8B, 9B, 10B, 11B, 12B, 13B, 14B, 15B, and 16B are diagrams corresponding to cross-sections taken along a line X1-X1′ of FIGS. 3A, 4A, 5A, 6A, 7A, 8A, 9A, 10A, 11A, 12A, 13A, 14A, 15A, and 16A.

Referring to FIGS. 3A and 3B, the substrate 102 may be provided, wherein the substrate 102 includes the first region CR and the second region PR with different densities of active regions, and the adjacent region IF that is adjacent to the first region CR within the second region PR. In one or more embodiments, the first region CR may be a cell array region, and the second region PR may be a peripheral circuit region.

The substrate 102 may include a semiconductor element such as silicon (Si) or germanium (Ge) or at least one compound semiconductor selected from among silicon-germanium (SiGe), silicon carbide (SiC), gallium arsenide (GaAs), indium arsenide (InAs), and indium phosphide (InP). The substrate 102 may include a conductive region, for example, a well doped with impurities or a structure doped with impurities.

A pad oxide layer 104 covering the substrate 102 may be formed thereon, and a hard mask layer 106 covering the pad oxide layer 104 may be formed thereon.

In one or more embodiments, the hard mask layer 106 may be a single layer. Alternatively, the hard mask layer 106 may have a multilayered structure in which two or more hard mask layers with different etching characteristics are stacked under certain etching conditions. For example, the hard mask layer 106 may include a silicon nitride layer, a silicon oxide layer, or a combination thereof. When the hard mask layer 106 includes a silicon oxide layer, the pad oxide layer 104 may be omitted.

On the hard mask layer 106, a buffer mask layer 110 covering the hard mask layer 106, a dual mask layer 112 covering the buffer mask layer 110, and a variable mask layer 114 covering the dual mask layer 112 may be sequentially formed.

In one or more embodiments, the buffer mask layer 110 may include a material with an etch selectivity that is different from that of the hard mask layer 106 under certain etching conditions. In one or more embodiments, the buffer mask layer 110 may include polysilicon.

A portion of the dual mask layer 112, which is formed in the first region CR, may be used as a layer for forming a plurality of etch mask patterns, and a portion of the dual mask layer 112, which is formed in the adjacent region IF and the second region PR, may be used as an etch mask covering the adjacent region IF and the second region PR.

In one or more embodiments, the dual mask layer 112 may include a carbon-containing layer such as the aforementioned SOH or an amorphous carbon layer (ACL). In one or more embodiments, the dual mask layer 112 may include any one material selected from among silicon-containing materials such as SiO₂, Si₃N₄, SiCN, and polysilicon.

The variable mask layer 114 may be variably formed as an etch mask for the dual mask layer 112. Similar to the dual mask layer 112, a portion of the variable mask layer 114, which is formed in the first region CR, may be used as a layer for forming a plurality of etch mask patterns, and a portion of the variable mask layer 114, which is formed in the adjacent region IF and the second region PR, may be used as an etch mask covering the adjacent region IF and the second region PR.

In one or more embodiments, the variable mask layer 114 may include a material with an etch selectivity that is different from that of the dual mask layer 112 so that the variable mask layer 114 may be used as an etch mask for the dual mask layer 112. For example, the variable mask layer 114 may include any one material selected from among silicon-containing materials such as SiON, SiO₂, Si₃N₄, SiCN, and polysilicon. Alternatively, the variable mask layer 114 may include metal or organic materials.

A capping mask layer 120 covering the variable mask layer 114 may be formed thereon. A portion of the capping mask layer 120, which is formed in the first region CR, may be removed during subsequent processes, and a portion of the capping mask layer 120, which is formed in the adjacent region IF and the second region PR, may be used as an etch mask covering the adjacent region IF and the second region PR.

In one or more embodiments, the capping mask layer 120 may include a material with an etch selectivity that is different from that of the variable mask layer 114 so that the capping mask layer 120 may be used as an etch mask for the variable mask layer 114. For example, the capping mask layer 120 may include an oxide layer.

On the capping mask layer 120, a first etch pattern M1 may be formed, wherein the first etch pattern M1 covers the adjacent region IF and the second region PR except the first region CR. The first etch pattern M1 may expose a portion of the capping mask layer 120 in the first region CR and cover a portion of the capping mask layer 120 in the adjacent region IF and the second region PR. In one or more embodiments, the first etch pattern M1 may fully expose the portion of the capping mask layer 120 in the first region CR and completely cover the portion of the capping mask layer 120 in the adjacent region IF and the second region PR. In one or more embodiments, the first etch pattern M1 may fully expose the portion of the capping mask layer 120 in the first region CR, expose a boundary region of the capping mask layer 120 between the adjacent region IF and the second region PR, and cover the remaining portions. However, the foregoing is only an example, and the shape of the first etch pattern M1 is not limited thereto.

In one or more embodiments, the first etch pattern M1 may have a stack structure in which an anti-reflection layer including an organic material or an inorganic material and a photoresist layer are stacked, but one or more embodiments are not limited thereto.

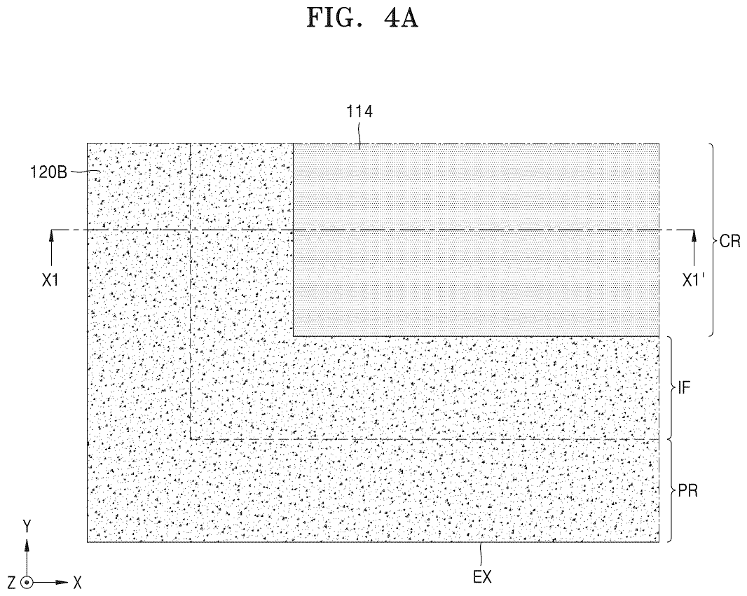

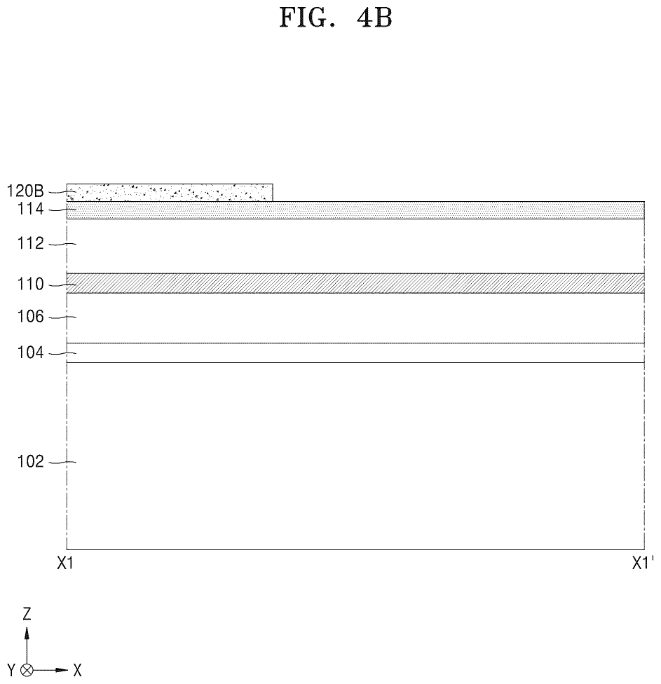

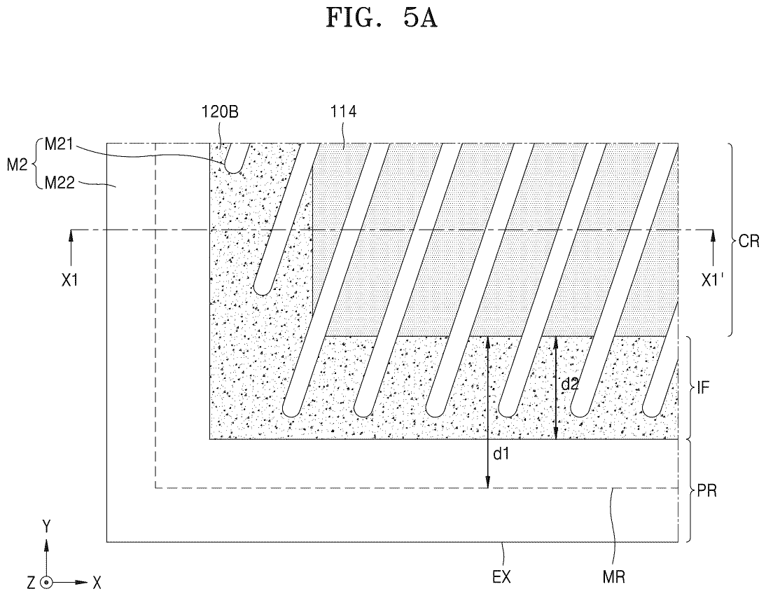

Referring to FIGS. 4A and 4B, the capping mask layer (120 of FIGS. 3A and 3B) may be etched using the first etch pattern (M1 of FIGS. 3A and 3B) as an etch mask, thus forming a capping mask line 120B. The capping mask line 120B may be formed along the shape of the first etch pattern M1. For example, the capping mask line 120B may expose a portion of the variable mask layer 114 in the first region CR and may cover a portion of the variable mask layer 114 in the adjacent region IF and the second region PR.

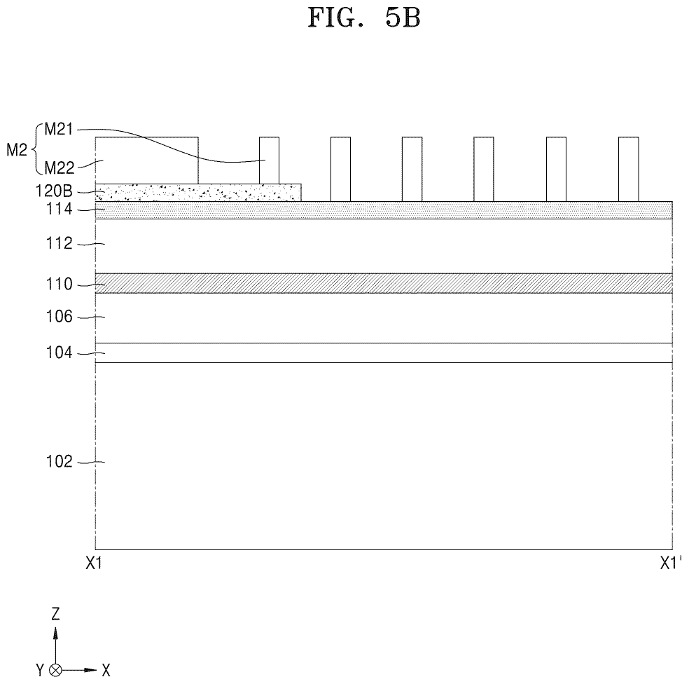

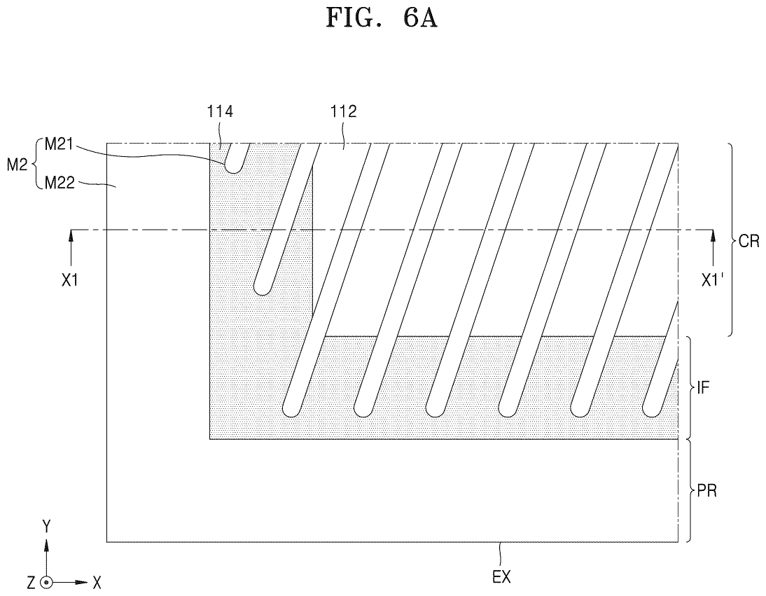

Referring to FIGS. 5A and 5B, a second etch pattern M2 may be formed on the results of FIGS. 4A and 4B. The second etch pattern M2 may include a plurality of first etch mask lines M21 in the first region CR and the adjacent region IF and a second etch mask line M22 in the second region PR.

In one or more embodiments, the first etch mask lines M21 may extend in a diagonal direction relative to the first horizontal direction (the X direction) and the second horizontal direction (the Y direction) and may be arranged apart from each other (i.e., separated from each other) in the first horizontal direction (the X direction) and the second horizontal direction (the Y direction). The first etch mask lines M21 may have line shapes extending in the diagonal direction. In one or more embodiments, the second etch mask lines M22 may include portions extending in the first horizontal direction (the X direction) and the second horizontal direction (the Y direction).

The first etch mask lines M21 may cover a portion of the first region CR and a portion of the adjacent region IF. In one or more embodiments, the first etch mask lines M21 may cover a portion of the variable mask layer 114 in the first region CR, and a portion of the capping mask line 120B in the adjacent region IF. The second etch mask lines M22 may entirely cover the second region PR. In one or more embodiments, the second etch mask lines M22 may cover a portion of the capping mask line 120B within the second region PR.

In one or more embodiments, the horizontal width of the first etch mask line M21 may correspond to a minimum feature size of a semiconductor device to be manufactured, and may be in a range from about several nanometers (nm) to about several tens of nm. In one or more embodiments, the horizontal width of the second etch mask line M22 may be greater than the minimum feature size.

The second etch pattern M2 may have a stack structure in which an anti-reflection layer including an organic material or an inorganic material and a photoresist layer are stacked, but one or more embodiments are not limited thereto.

As shown in FIG. 5A, in a patterning region MR for patterning the first active regions AC1 in the first region CR, a minimum margin horizontal width required during the patterning process may be defined as a first length d1, and the horizontal width of the adjacent region IF may be defined as a second length d2. In other words, the first length d1 may be defined as a length from an edge of the first region CR to an edge of the patterning region MR (that is, an edge of a region where the first etch mask lines M21 are formed), and the second length d2 may be defined as a length from an edge of the first region CR to an edge of the adjacent region IF. In one or more embodiments, the first length d1 may be greater than the second length d2. In other words, the horizontal width of the adjacent region IF may be less than the minimum margin horizontal width required during the patterning process.

In the present disclosure, the pad oxide layer 104, the hard mask layer 106, the buffer mask layer 110, the dual mask layer 112, and the variable mask layer 114, which are distinguished as mask lines or mask patterns used in the patterning process of the active regions in the first region CR, except for the capping mask line 120B, may be referred to as a “mask stack.”

In addition, the mask lines or mask patterns used in the subsequent patterning process of the active regions, that is, a pad oxide layer pattern 104P, a hard mask pattern 106P, a first buffer mask pattern 110AP, a second buffer mask pattern 110BP, a first buffer mask line 110A, a second buffer mask line 110B, a first dual mask line 112A, a second dual mask line 112B, a first variable mask line 114A, a second variable mask line 114B, and a capping mask pattern 120BP may be referred as “mask patterns.”

According to the mask structure shown in FIGS. 5A and 5B, the capping mask line 120B may help reduce or prevent the formation of parasitic mask patterns in the adjacent region IF and the second region PR during the patterning process of the active regions. For example, even if the first etch mask lines M21 extend from the first region CR to the adjacent region IF and the second region PR, the capping mask line 120B serves as an etch mask along with the first etch mask lines M21 during the process of etching the mask stack by using the first etch mask lines M21 as etch masks, and thus, the formation of parasitic mask patterns in the adjacent region IF and the second region PR may be reduced or prevented. Thus, a mask structure that does not require a separate trimming process to remove the parasitic mask pattern may be provided.

Moreover, according to the mask structure shown in FIGS. 5A and 5B, because parasitic active regions are not formed in the adjacent region IF and the second region PR as the parasitic mask patterns are not formed due to the capping mask line 120B, a mask structure capable of reducing or preventing the formation of the parasitic active regions may be provided even if the second length d2, which is the horizontal width of the adjacent region IF is designed to be relatively less than the first length d1, which is the minimum margin horizontal width required during the patterning process.

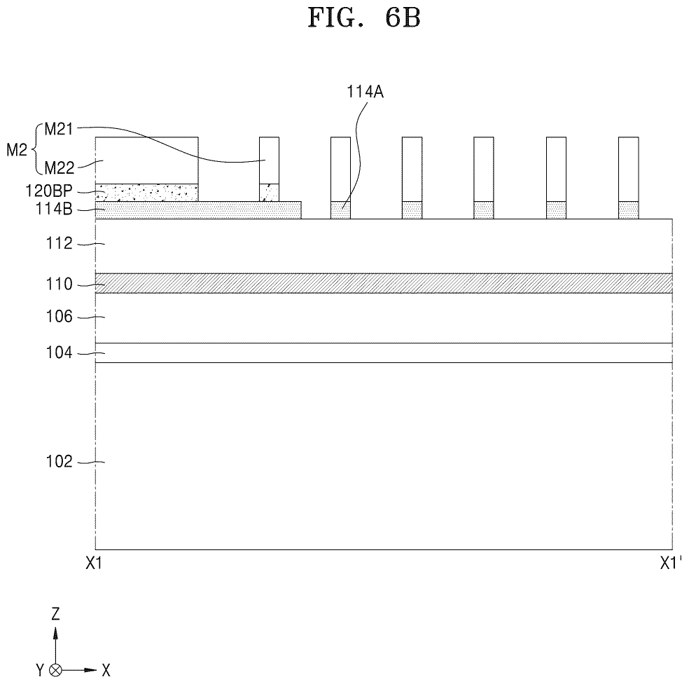

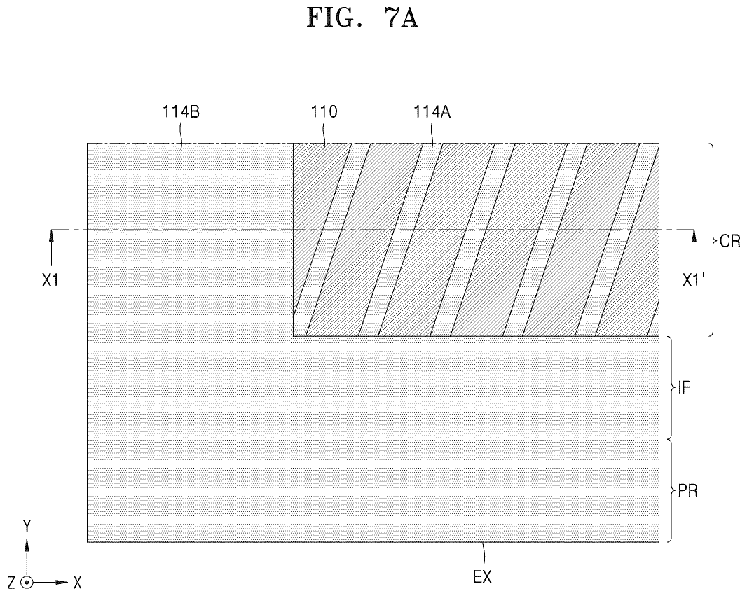

Referring to FIGS. 6A and 6B, the capping mask pattern 120BP may be formed by etching the capping mask line (120B of FIGS. 5A and 5B) by using the second etch pattern M2 as an etch mask, the first variable mask lines 114A may be formed by etching the variable mask layer (114 of FIGS. 5A and 5B) with the second etch pattern M2 as an etch mask, and the second variable mask line 114B may be formed by etching the variable mask layer (114 of FIGS. 5A and 5B) with the capping mask line (120 of FIGS. 5A and 5B) as an etch mask.

The capping mask pattern 120BP may be formed in the second region PR. In one or more embodiments, the capping mask pattern 120BP may cover a portion of the second variable mask line 114B in the second region PR.

The first variable mask lines 114A may be formed in the first region CR. Similar to the first etch mask lines M21, the first variable mask lines 114A may extend in the diagonal direction relative to the first horizontal direction (the X direction) and the second horizontal direction (the Y direction) and may be arranged apart from each other in the first horizontal direction (the X direction) and the second horizontal direction (the Y direction). The first variable mask lines 114A may have line shapes extending in the diagonal direction. In one or more embodiments, the first variable mask lines 114A may cover a portion of the dual mask layer 112 in the first region CR.

The second variable mask line 114B may be formed in the adjacent region IF and the second region PR. In one or more embodiments, the second variable mask line 114B may cover a portion of the dual mask layer 112 in the adjacent region IF and the second region PR.

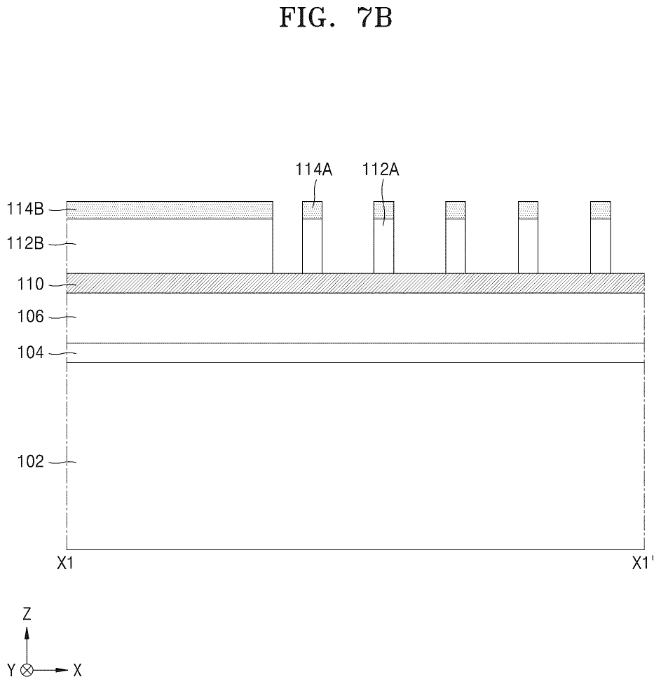

Referring to FIGS. 7A and 7B, the first dual mask lines 112A may be formed by etching a portion of the mask layer (112 of FIGS. 6A and 6B) by using the first variable mask line 114A as an etch mask, and the second dual mask line 112B may be formed by etching a portion of the mask layer (112 of FIGS. 6A and 6B) using the second variable mask line 114B as an etch mask.

The first dual mask lines 112A may be formed in the first region CR. Similar to the first variable mask lines 114A, the first dual mask lines 112A may extend in the diagonal direction relative to the first horizontal direction (the X direction) and the second horizontal direction (the Y direction) and may be arranged apart from each other in the first horizontal direction (the X direction) and the second horizontal direction (the Y direction). The first dual mask lines 112A may have line shapes extending in the diagonal direction. In one or more embodiments, the first dual mask lines 112A may cover a portion of the buffer mask layer 110 in the first region CR.

The second dual mask line 112B may be formed in the adjacent region IF and the second region PR. In one or more embodiments, the second dual mask line 112B may cover a portion of the buffer mask layer 110 in the adjacent region IF and the second region PR.

In one or more embodiments, while the etching process is performed to form the first dual mask lines 112A and the second dual mask line 112B, the first variable mask lines 114A and the second variable mask line 114B may also be etched due to the influence of the etching atmosphere. In this case, because the horizontal widths of the first variable mask lines 114A are relatively less than that of the second variable mask line 114B, the etching amount of the first variable mask lines 114A may be relatively greater than that of the second variable mask line 114B. Therefore, the vertical thickness of the first variable mask lines 114A may be relatively greater than that of the second variable mask line 114B.

In one or more embodiments, the etching process of forming the first dual mask lines 112A and the second dual mask line 112B may be performed as dry etching, and when the mask layer (112 of FIGS. 6A and 6B) includes SOH, a plasma etching process using a mixed gas of O₂ and Ar may be employed.

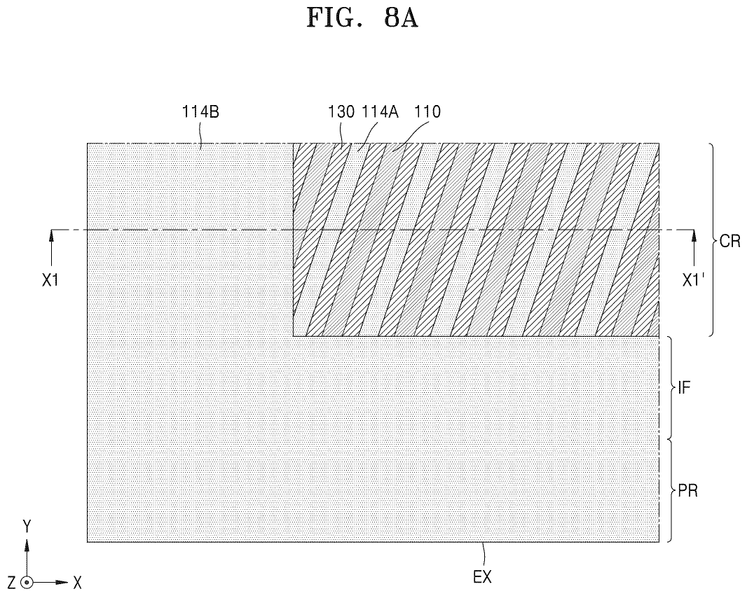

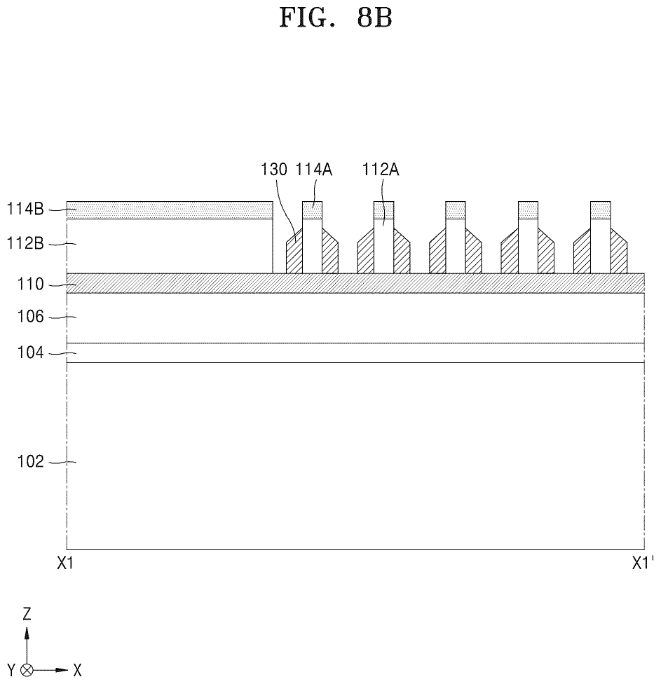

Referring to FIGS. 8A and 8B, spacers 130 may be formed on both sidewalls of each of the first dual mask lines 112A.

To form the spacers 130, a spacer mask layer conformally covering the upper surfaces of the results of FIGS. 7A and 7B may be formed. The spacer mask layer may include a material with an etch selectivity that is different from that of each of the first variable mask line 114A, the second variable mask line 114B, the first dual mask line 112A, the second dual mask line 112B, and the buffer mask layer 110. For example, the spacer mask layer may include an oxide layer. For example, the spacer mask layer may be deposited through Atomic Layer Deposition (ALD).

The spacer mask layer may be etched when the upper surface of the buffer mask layer 110 is exposed, thus forming the spacers 130. FIGS. 8A and 8B show that the spacers 130 are formed on both sidewalls of each first dual mask line 112A. However, the spacers 130 may also be formed on the sidewalls of the second dual mask line 112B.

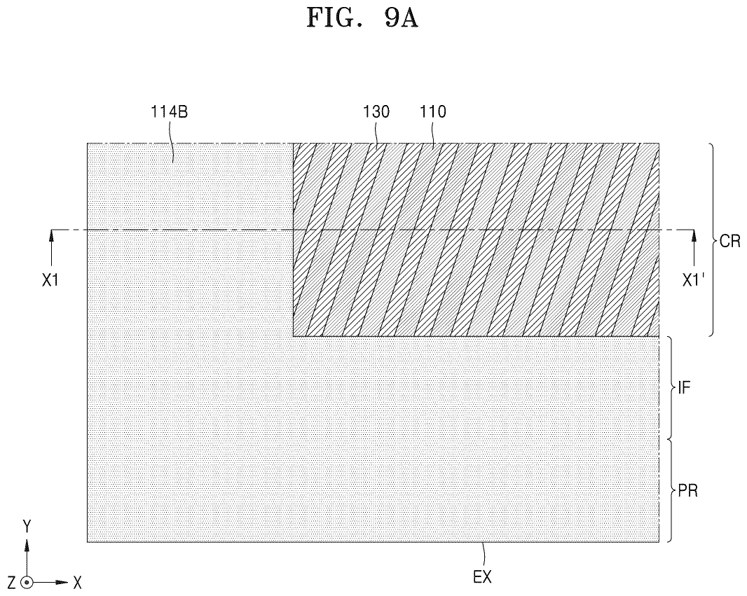

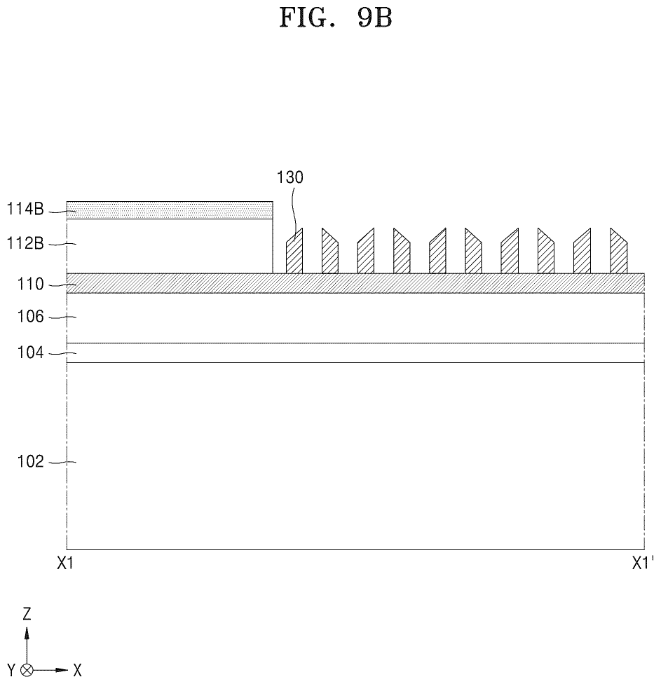

Referring to FIGS. 9A and 9B, only the first variable mask line 114A is selectively removed from among the first variable mask line 114A and the second variable mask line 114B such that the first dual mask line 112A may only be exposed externally from among the first dual mask line 112A and the second dual mask line 112B.

For the selective removal of the first variable mask line 114A, the difference in etch selectivity between the first variable mask line 114A, the buffer mask layer 110, the first dual mask line 112A, and the spacer 130 may be utilized. In this case, because the vertical thickness of the first variable mask line 114A is less than that of the second variable mask line 114B and the horizontal width of the first variable mask line 114A is less than that of the second variable mask line 114B, the etching mount of the first variable mask line 114A may be significantly greater than that of the second variable mask line 114B. Therefore, at the point in time when the first variable mask line 114A is completely removed, the second variable mask line 114B may remain without significant thickness reduction.

Then, in the first region CR, the exposed first dual mask line 112A is removed, thereby exposing a portion of the buffer mask layer 110 through the space between the spacers 130. In the adjacent region IF and the second region PR, a portion of the buffer mask layer 110 in the adjacent region IF and the second region PR may be covered by the second dual mask line 112B and the second variable mask line 114B.

The removal process of the first dual mask line 112A may utilize, for example, ashing and stripping or either dry etching or wet etching.

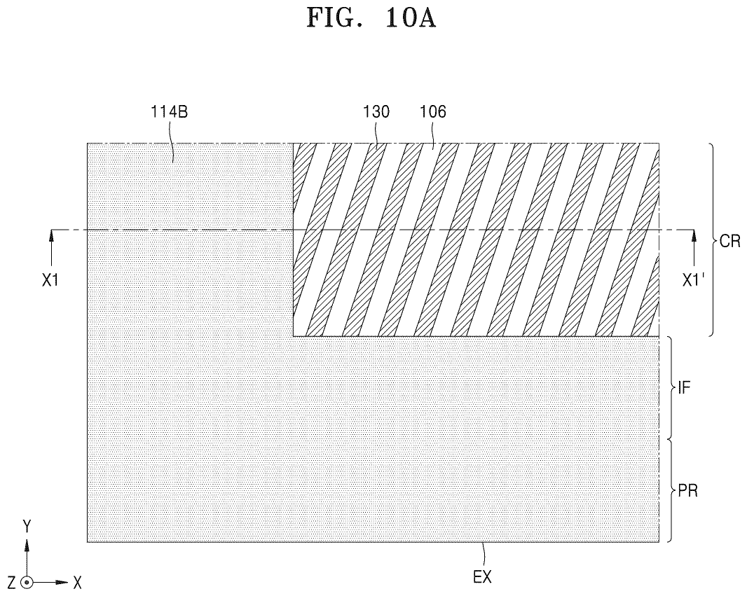

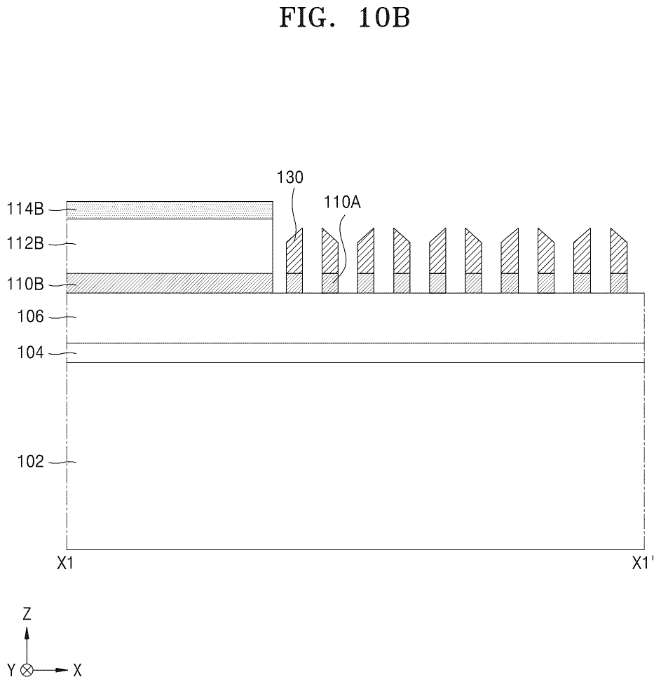

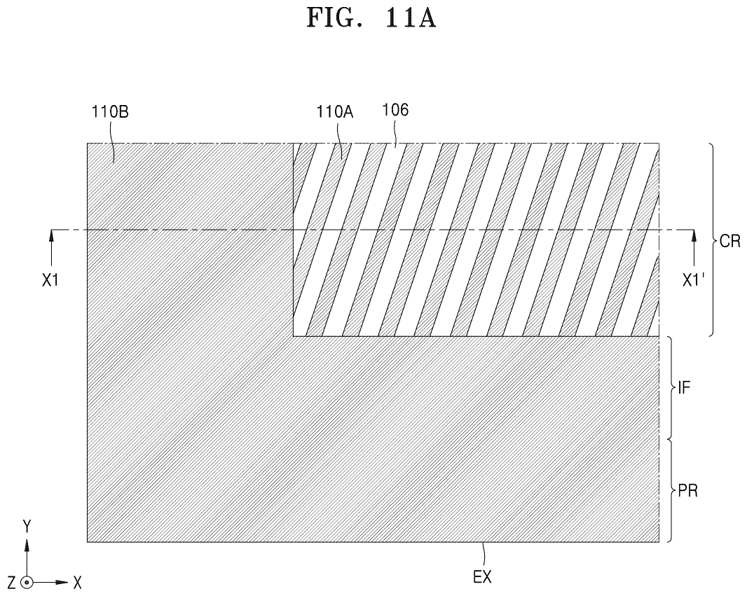

Referring to FIGS. 10A and 10B, the first buffer mask lines 110A may be formed by etching the buffer mask layer 110 by using the spacers 130 as etch masks, and the second buffer mask lines 110B may be formed by etching the buffer mask layer 110 by using the second dual mask line 112B and the second variable mask line 114B as etch masks.

Similar to the spacers 130, the first buffer mask lines 110A may have line shapes extending in the diagonal direction relative to the first horizontal direction (the X direction) and the second horizontal direction (the Y direction) and may be arranged apart from each other in the first horizontal direction (the X direction) and the second horizontal direction (the Y direction). The first buffer mask lines 110A may be arranged in the first region CR, and a portion of the hard mask layer 106 in the first region CR may be exposed through the space between the first buffer mask lines 110A.

The second buffer mask line 110B may include a portion extending in the first horizontal direction (the X direction) and the second horizontal direction (the Y direction). The second buffer mask line 110B may cover the adjacent region IF and the second region PR and also cover a portion of the hard mask layer 106 in the adjacent region IF and the second region PR.

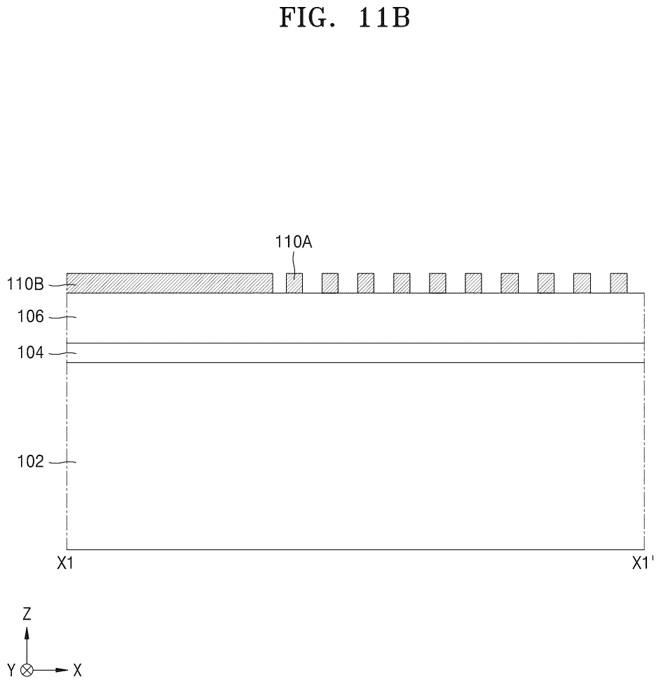

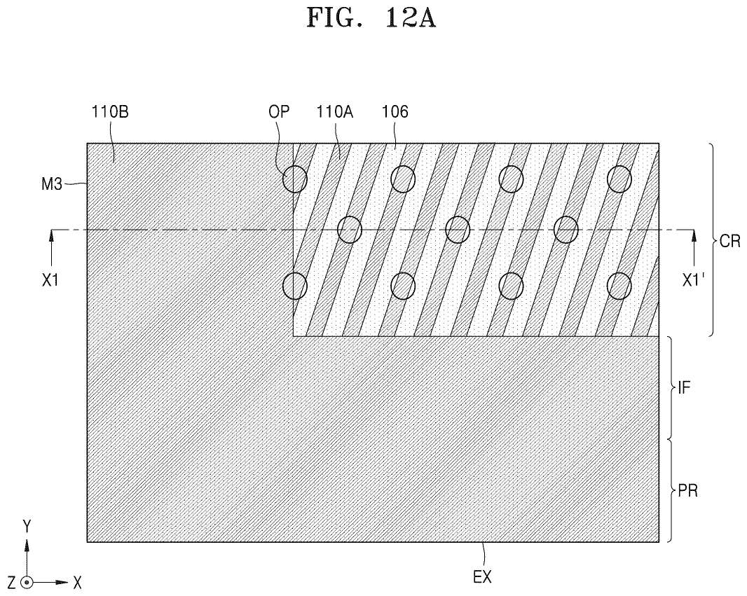

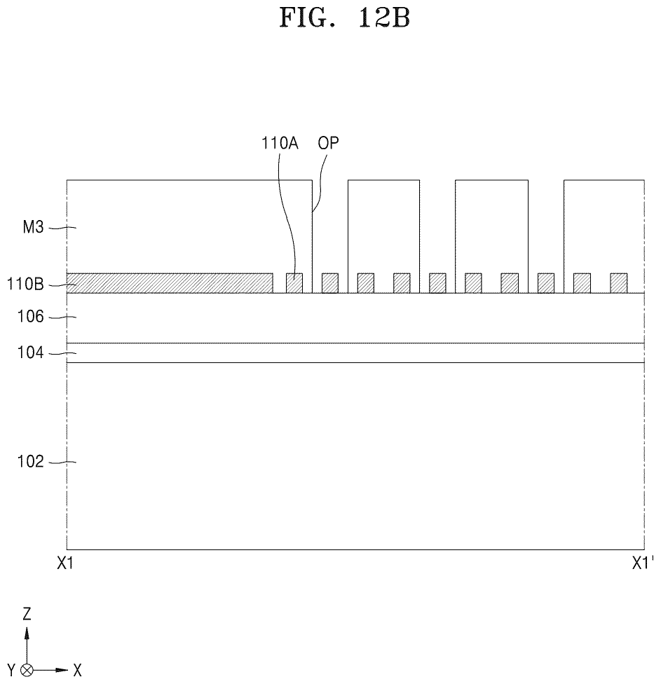

Referring to FIGS. 11A and 11B, the first buffer mask lines 110A and the second buffer mask line 110B may be formed through the aforementioned processes shown in FIGS. 5A to 10B. However, the foregoing is only an example, and the first buffer mask lines 110A and the second buffer mask line 110B may be formed through various processes other than the processes described above with reference to FIGS. 5A to 10B. For example, referring to FIGS. 5A and 5B, the first etch mask lines M21 may be formed at positions corresponding to the first buffer mask lines 110A, and the first buffer mask lines 110A and the second buffer mask line 110B may be formed through the patterning process. When the first buffer mask lines 110A and the second buffer mask line 110B are formed through the processes described above with reference to FIGS. 5A to 10B, the subsequent processes shown in FIGS. 12A and 12B may also be performed while maintaining the second dual mask line 112B, the second variable mask line 114B, and the spacers 130.

Referring to FIGS. 12A and 12B, a third etch pattern M3 may be formed on the results of FIGS. 11A and 11B. The third etch pattern M3 may be used as a trimming pattern used during the trimming process of defining the active regions in the first region CR. The third etch pattern M3 may be formed to cover the first region CR, the adjacent region IF, and the second region PR.

The third etch pattern M3 may include a plurality of openings OP, and the openings OP may be spaced apart from each other in the first region CR. The openings OP may be formed at regular pitches along the longitudinal direction of the first buffer mask lines 110A. For example, the openings OP may have widths that are equal to or greater than the horizontal widths of the first buffer mask lines 110A in the first horizontal direction (the X direction) but less than the spacing between the first buffer mask lines 110A in the first horizontal direction (the X direction). Portions of the first buffer mask lines 110A may be exposed through the openings OP.

In one or more embodiments, the third etch pattern M3 may be formed through various processes such as spin coating or CVD. For example, after an organic compound layer with a great thickness is formed on a substrate, the organic compound layer is first baked at a temperature ranging from about 150° C. to about 250° C. to form a carbon-containing layer and then secondarily baked at a temperature ranging from about 300° C. to about 550° C., thereby being hardened. Then, the carbon-containing layer may be patterned through photolithography, and the third etch pattern M3 may be formed. The organic compound layer may include a hydrocarbon compound containing an aromatic ring such as phenyl, benzene, or naphthalene, or derivatives thereof. The first etch pattern M1 and the second etch pattern M2 described above may also be formed through processes similar to those for the third etch pattern M3.

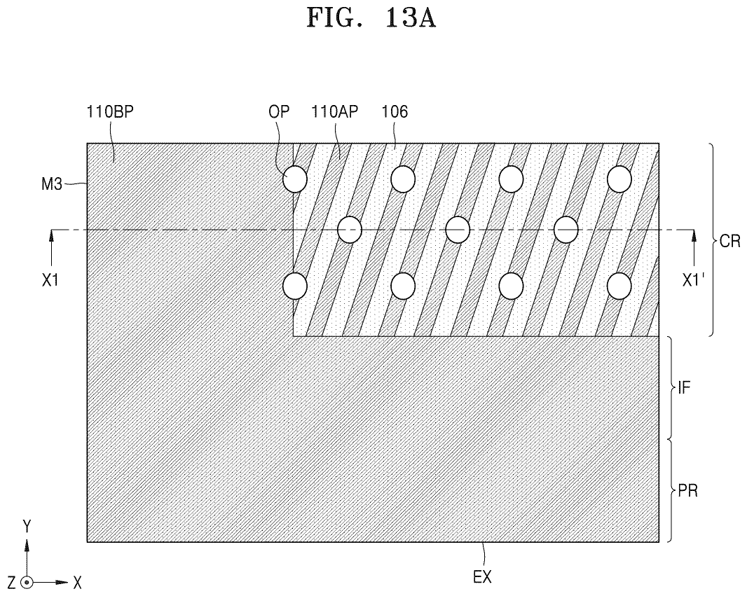

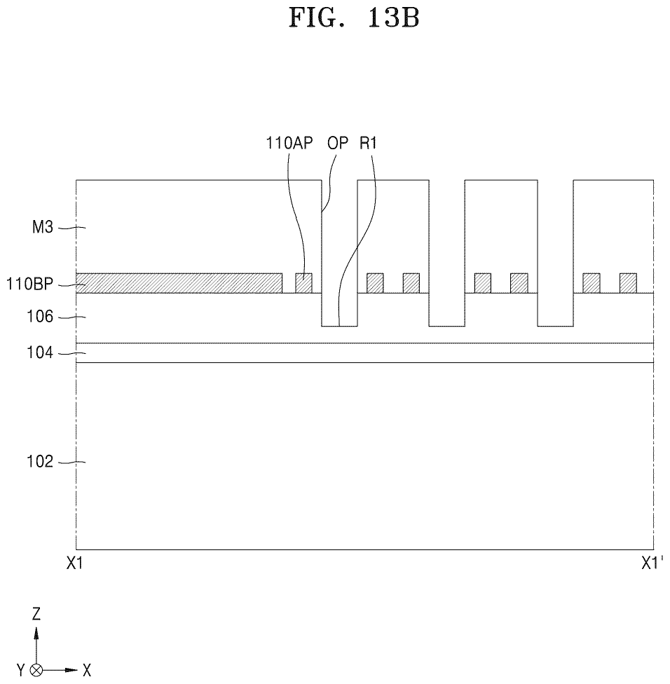

Referring to FIGS. 13A and 13B, a trimming process of removing the exposed portions of the first buffer mask lines 110A by using the third etch pattern M3 as an etch mask may be performed. The first buffer mask lines 110A may be separated into a plurality of first buffer mask patterns 110AP through the trimming process described above.

While the trimming process is performed through the openings OP to form the first buffer mask patterns 110AP, portions of the hard mask layer 106, which are exposed through the openings OP, may also be removed. Thus, a plurality of recesses R1 may be formed in the hard mask layer 106 at positions corresponding to the openings OP in the vertical direction (the Z direction).

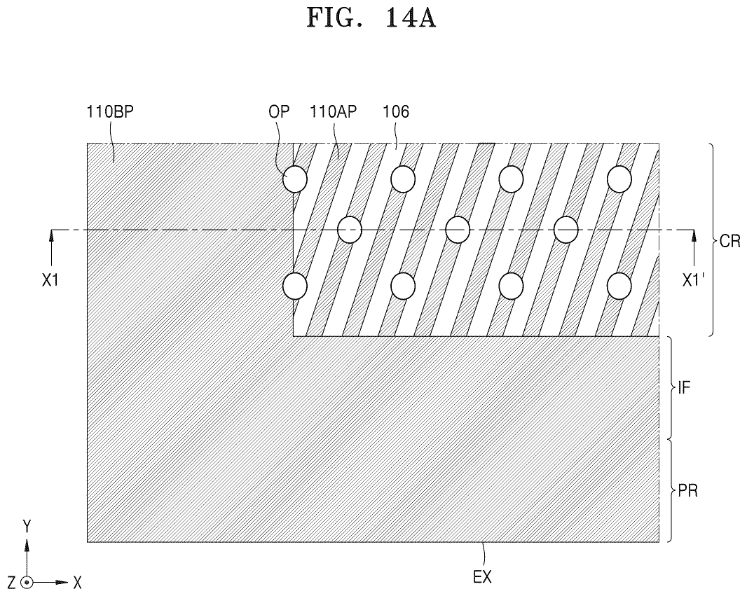

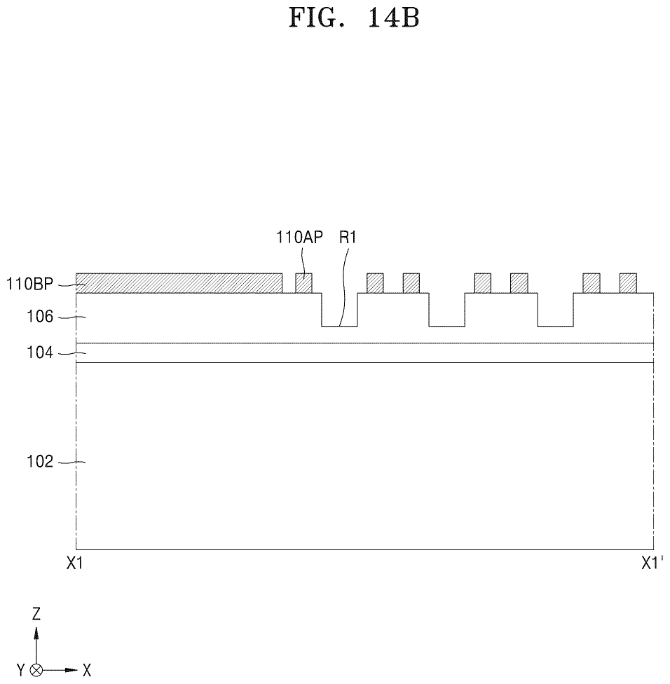

Referring to FIGS. 14A and 14B, the third etch pattern M3 is removed from the results of FIGS. 13A and 13B, thus exposing the first buffer mask patterns 110AP and the second buffer mask pattern 110B.

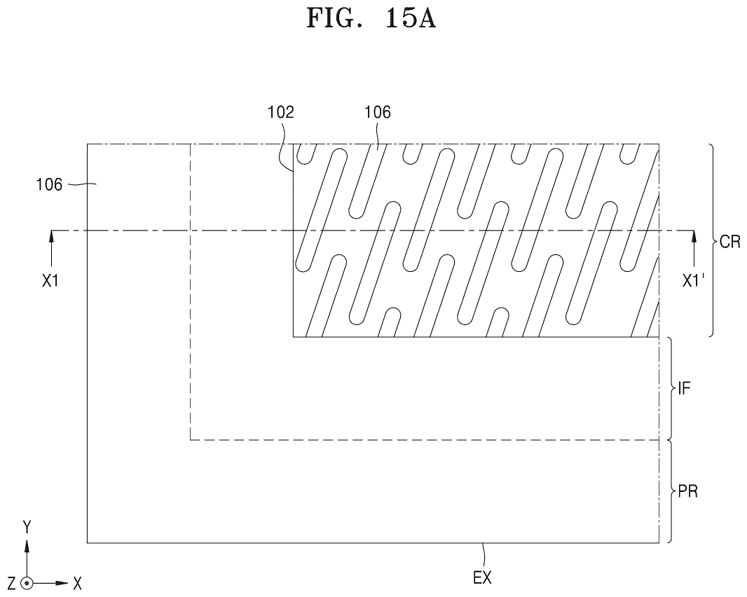

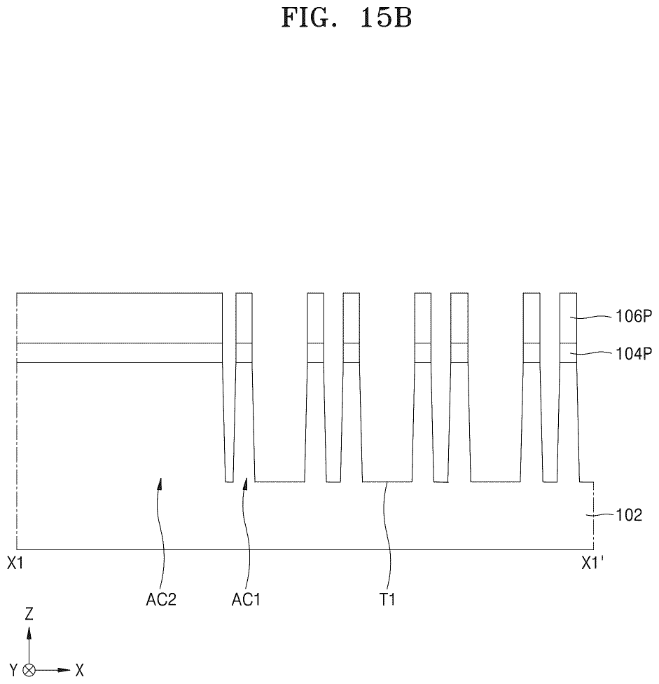

Referring to FIGS. 15A and 15B, the hard mask pattern 106P may be formed by etching the hard mask layer 106 by using the first buffer mask patterns 110AP and the second buffer mask pattern 110B of FIGS. 14A and 14B as etch masks, and the pad oxide layer 104 and the substrate 102 may be sequentially etched using the hard mask pattern 106P as an etch mask, thereby forming a plurality of trenches T1 in the first region CR. The first active regions AC1 may be defined by the trenches T1 in the first region CR, and the second active regions AC2 may be defined by trenches that are positioned between the adjacent region IF and the first region CR among the trenches T1.

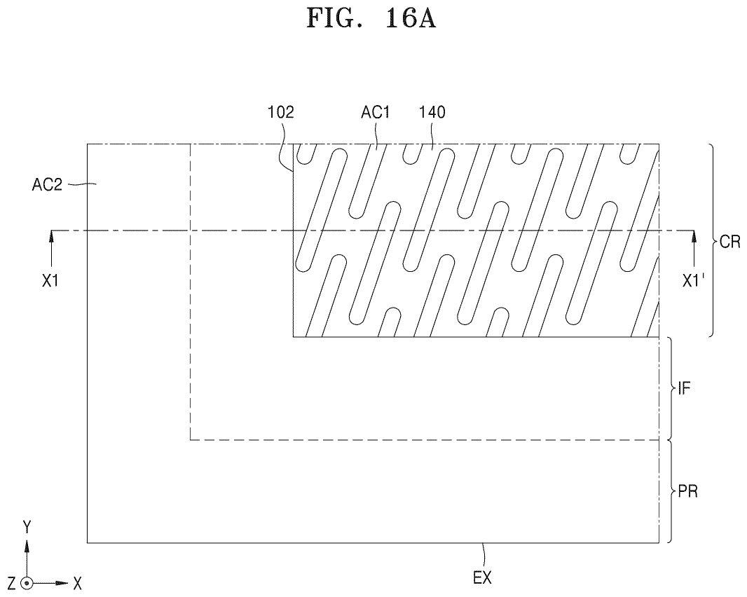

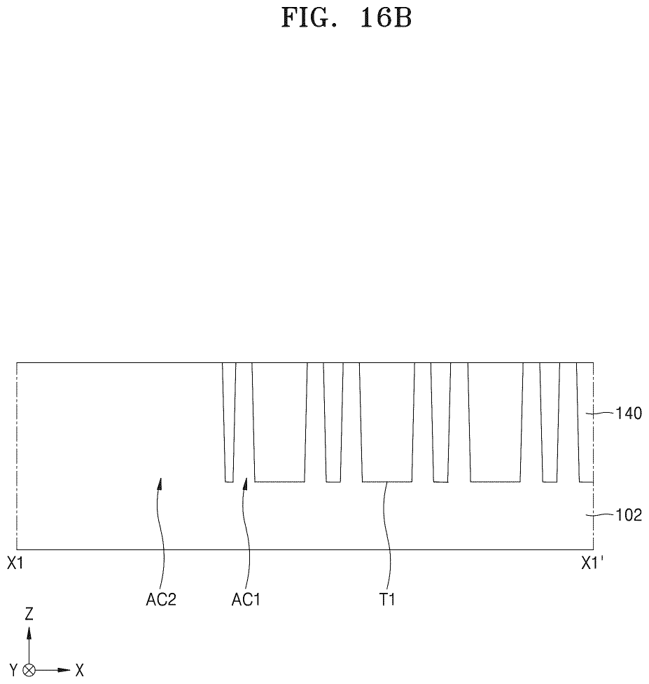

Referring to FIGS. 16A and 16B, the pad oxide layer (104 of FIGS. 15A and 15B) and the hard mask pattern (106P of FIGS. 15A and 15B) on the substrate 102 may be removed, thus exposing the upper surfaces of the first active regions AC1 and the second active regions AC2. Then, a device isolation layer 140 may be formed by filling the trenches T1 with insulating materials. The device isolation layer 140 may include an oxide layer, a nitride layer, or a combination thereof.

However, the structure of the semiconductor device according to embodiment is not limited to that shown in FIGS. 16A and 16B and may vary according to the structures of the first etch pattern M1 and the capping mask line 120B formed based on the formation of the first etch pattern M1. For example, the first etch pattern M1, which exposes the boundary region between the adjacent region IF and the second region PR, and the capping mask line 120B formed based on the first etch pattern M1 may be formed, and accordingly, a dummy active region or a device isolation layer may also be further formed in the boundary region between the adjacent region IF and the second region PR.

According to the one or more embodiments of the disclosure, the capping mask line 120B covering the adjacent region IF and the second region PR (for example, the peripheral circuit region) may be formed before the patterning process of the mask structure for forming the active regions, in other words, the patterning process of forming the mask patterns extending in the first region CR (e.g., a cell array region) in the diagonal direction relative to the first horizontal direction (the X direction) and the second horizontal direction (the Y direction), thereby reducing or preventing the formation of parasitic mask patterns in the adjacent region IF and the second region PR through the patterning process. Thus, because no separate trimming process of removing parasitic mask patterns is required, a method of manufacturing a semiconductor device may be relatively simplified.

Furthermore, according to the one or more embodiments of the disclosure, because parasitic active regions are not formed due to parasitic mask patterns, the formation of the parasitic active regions in the second region PR may be reduced or prevented even if a horizontal width (d2 of FIG. 2) of the adjacent region IF is designed to be relatively less than a minimum margin horizontal width (d1 of FIG. 2) required during the patterning process; thus, a method of manufacturing an increasingly integrated semiconductor device may be provided.

While the disclosure has been particularly shown and described with reference to one or more embodiments thereof, it will be understood that various changes in form and details may be made therein without departing from the spirit and scope of the following claims.

What is claimed is:

1. A method of manufacturing a semiconductor device, the method comprising:
forming a mask stack on a substrate, wherein the substrate comprises a first region, a second region and an adjacent region between the first region and the second region, and wherein the first region and the second region have different active region densities;
forming a capping mask layer on the mask stack;
forming, on the capping mask layer, a first etch pattern that does not cover the first region and is on the second region and the adjacent region;
forming a capping mask line by removing a portion of the capping mask layer by using the first etch pattern as an etch mask and exposing a portion of the mask stack;
forming a second etch pattern on the capping mask line and the exposed portion of the mask stack;
forming a mask pattern by removing a portion of the mask stack using the capping mask line and the second etch pattern as etch masks; and
forming a plurality of trenches in the substrate by using the mask pattern as an etch mask,
wherein the second etch pattern comprises:
a plurality of first etch mask lines extending in one direction in the first region and the adjacent region, wherein the plurality of first etch mask lines are separated from each other; and
a second etch mask line on the second region.

2. The method of claim 1,
wherein the first etch pattern extends in a first horizontal direction and a second horizontal direction,
wherein the plurality of first etch mask lines extend in a diagonal direction relative to the first horizontal direction and the second horizontal direction, and
wherein the second etch mask line of the second etch pattern extends in the first horizontal direction and the second horizontal direction.

3. The method of claim 1, wherein the capping mask line does not cover the first region and is on the adjacent region and the second region.

4. The method of claim 1, wherein the capping mask line comprises an oxide layer.

5. The method of claim 1,
wherein the forming the mask stack comprises sequentially stacking a hard mask layer, a buffer mask layer, a dual mask layer, and a variable mask layer,
wherein the variable mask layer comprises a material that is different from a material of the dual mask layer,
wherein an etch selectivity of the material of the variable mask layer is different from an etch selectivity of the material the dual mask layer,
wherein the buffer mask layer comprises a material that is different from a material of the hard mask layer, and
wherein an etch selectivity of the material of the buffer mask layer is different from an etch selectivity of the material of the hard mask layer.

6. The method of claim 1,
wherein the forming the mask stack comprises sequentially stacking a hard mask layer, a buffer mask layer, a dual mask layer, and a variable mask layer, and
wherein the forming the capping mask line further comprises exposing a portion of the variable mask layer in the first region without exposing a portion of the variable mask layer in the adjacent region and the second region.

7. The method of claim 1,
wherein the forming the mask stack comprises sequentially stacking a hard mask layer, a buffer mask layer, a dual mask layer, and a variable mask layer, and
wherein the forming the mask pattern further comprises:
forming a plurality of first variable mask lines, which are spaced apart from each other in the first region, by etching the variable mask layer using the second etch pattern as an etch mask; and
forming a second variable mask line in the second region and the adjacent region using the second etch pattern and the capping mask line as etch masks.

8. The method of claim 7,
wherein the forming the plurality of first variable mask lines further comprises forming the plurality of first variable mask lines on a portion of the dual mask layer in the first region, and
wherein the forming the second variable mask line further comprises forming the second variable mask line on a portion of the dual mask layer in the adjacent region and the second region.

9. The method of claim 7, wherein the forming the mask pattern further comprises, after the forming of the plurality of first variable mask lines and the forming of the second variable mask line:
forming a plurality of first dual mask lines by etching the dual mask layer using the plurality of first variable mask lines as etch masks; and
forming a second dual mask line by etching the dual mask layer using the second variable mask line as an etch mask.

10. The method of claim 1,
wherein the plurality of first etch mask lines are in a patterning region,
wherein a first length is defined as a length from an edge of the first region to an edge of the patterning region,
wherein a second length is defined as a length from the edge of the first region to an edge of the adjacent region, and
wherein the second length is less than the first length.

11. A method of manufacturing a semiconductor device, the method comprising:
sequentially depositing a dual mask layer, a variable mask layer, and a capping mask layer on a substrate, the substrate comprising a cell array region, a peripheral circuit region, and an interface region, wherein the interface region is between the cell array region and the peripheral circuit region;
forming, on the capping mask layer, a first etch pattern that does not cover the cell array region and is on the interface region and the peripheral circuit region;
forming a capping mask line by removing a portion of the capping mask layer by using the first etch pattern as an etch mask and exposing a portion of the variable mask layer;
forming a second etch pattern on the capping mask line and the exposed portion of the variable mask layer; and
etching the variable mask layer using the capping mask line and the second etch pattern as etch masks,
wherein the second etch pattern comprises:
a plurality of first etch mask lines that are spaced apart from each other in the cell array region and the interface region; and
a second etch mask line on the peripheral circuit region.

12. The method of claim 11, wherein the capping mask line comprises a material that is different from a material of the variable mask layer, and wherein an etch selectivity of the material of the capping mask line is different from an etch selectivity of the variable mask layer.

13. The method of claim 11,
wherein the capping mask line comprises an oxide layer, and
wherein the variable mask layer comprises any one material selected from among SiON, Si₃N₄, SiCN, and polysilicon.

14. The method of claim 11,
wherein the first etch pattern extends in a first horizontal direction and a second horizontal direction,
wherein the plurality of first etch mask lines extend in a diagonal direction relative to the first horizontal direction and the second horizontal direction, and
wherein the second etch mask line of the second etch pattern extends in the first horizontal direction and the second horizontal direction.

15. The method of claim 11, wherein the capping mask line does not cover the cell array region and is on the interface region and the peripheral circuit region.

16. The method of claim 11, wherein the etching the variable mask layer further comprises:
forming a first variable mask line by etching a portion of the variable mask layer in the cell array region using the plurality of first etch mask lines as an etch mask; and
forming a second variable mask line by etching a portion of the variable mask layer in the interface region and the peripheral circuit region using the capping mask line as an etch mask.

17. The method of claim 16, wherein the etching the variable mask layer further comprises forming a capping mask pattern by etching the capping mask line using the second etch mask line and a portion of the plurality of first etch mask lines as etch masks.

18. The method of claim 16, further comprising:
after the etching the variable mask layer, forming a first dual mask line by etching the dual mask layer using the first variable mask line as an etch mask and forming a second dual mask line by etching the dual mask layer using the second variable mask line as an etch mask; and
forming spacers on sidewalls of the first dual mask line and the second dual mask line.

19. A mask structure comprising:
a hard mask layer on a substrate, the substrate comprising a first region, a second region, and an adjacent region between the first region and the second region, wherein the first region and the second region have different active region densities;
a dual mask layer comprising a carbon-containing layer on the hard mask layer;
a variable mask layer comprising a nitride layer on the dual mask layer; and
a capping mask line comprising an oxide layer on the variable mask layer,
wherein the capping mask line is on the adjacent region and the second region and does not cover the first region.

20. The mask structure of claim 19, further comprising, on the capping mask line and the variable mask layer:
a plurality of first mask lines extending in one direction in the first region and the adjacent region, wherein the plurality of first mask lines are separated from each other; and
a second mask line covering the second region,
wherein the plurality of first mask lines are arranged in a patterning region,
wherein a first length is defined as a length from an edge of the first region to an edge of the patterning region,
wherein a second length is defined as a length from the edge of the first region to an edge of the adjacent region, and
wherein the second length is less than the first length.
